(19) United States
(12) Patent Application Publication
(10) Pub. No.: US 2006/0139664 A1
(43) Pub. Date: Jun. 29, 2006

(54) High speed color match processing system and method thereof

(75) Inventors: Xing-Ping Zhou, Beijing (CN); Qiang Gu, Beijing (CN)

Correspondence Address: APEX JURIS, PLLC;TRACY M HEIMS, LAKE CITY CENTER, SUITE 410, 12360 LAKE CITY WAY NORTHEAST, SEATTLE, WA, 98125, US

(73) Assignee: Destiny Technology Corporation, Taipei (TW)

(21) Appl. No.: 11/021,212

(22) Filed: Dec. 23, 2004

(51) Int. Cl. G03F 3/08

(52) U.S. Cl. 358/1.9; 358/518

(57) ABSTRACT

A high-speed color match processing system and the method thereof convert RGB values into CMYK values and store them in a storage module. According to a conversion start command, the key words of RGB values of all pixels in the current digital picture are extracted. The corresponding CMYK values are searched using the key words in the storage module. The RGB values are then converted into the CMYK values.

### BACKGROUND OF THE INVENTION

1. Field of Invention

The invention relates to a color match processing system and the method thereof. In particular, it relates to a high-speed color match processing system and the method thereof.

2. Related Art

In computers, the color at each point in a picture is usually encoded using 24-bit RGB (red/green/blue) values, in which 8 bits represent red, 8 bits represent green, and the last 8 bits represent blue. The RGB colors on a screen cannot be directly printed out. This is because the light-emitting device (such as the computer monitor) generates colors by mixing the red, gree, and blue colors. The display process superimposes different colors in different proportions. For example, no light at all results in black. Superimposing all of the colors results in white. Contrary to this, a reflection device (such as a piece of paper) generates colors in the opposite way. A piece of white paper reflects colors of all wavelengths and thus appears to be white. The color printing process uses cyan, magenta, and yellow (CMY) dies to absorb colors of different wavelengths, thereby producing different colors. The cyan ink absorbs red light, thus presenting the bluish color. Likewise, the magenta ink abosrbs green light, thus showing the purplish color. A page in the RGB mode has to be printed in the CMY mode. Therefore, one has to change from the RGB mode to the CMY mode. After adding black to the CMY mode, we call this mode the CMYK mode, where K refers to black. Through the steps of colro conversion and half-tone conversion, a driver program converts the 24-bit RGB representation into the 4-bit CMYK representation used by the monochromic and color print heads. In color management, this kind of processing method is called the color match method (CMM).

Since various kinds of differences exist in color printing devices, the conversion of a picture from the RGB color space to the CMYK color space has to use a special match algorithm, but not the conventional mathematical theory algorithm. During the color match process of color laser printing, there may involve billions of operations if a page contains a large color image because each pixel in the page has to be converted. The long processing time may significantly slow down the system.

### SUMMARY OF THE INVENTION

In view of the foregoing, the invention provides a high-speed color match processing system and the method thereof. A primary objective of the invention is to increase the processing speed in the color match of digital pictures. At the same time, the invention reduces the use of system memory and, therefore, does not slow down the system operation.

To achieve the above objective, the invention provides a high-speed color match processing system to rapidly convert a digital picture from the RGB mode to the CMYK mode. The system includes a conversion pre-processing module to convert the RGB values to CMYK value, a storage module to store the CMYK values, a conversion control module to receive a conversion start command and control the beginning of the conversion, and an extracting module to extract the key word of the RGB value at a pixel of the digital picture according to the conversion start command and search in the storage module a CMYK value corresponding to the key word, thereby converting the RGB value to the CMYK value.

The invention further provides a high-speed color match processing method to rapidly convert a digital picture from the RGB mode to the CMYK mode. According to the method, the RGB values are first converted into CMYK values, which are then stored in a storage module. Afterwards, a conversion start command is received and the key words of the RGB values of all pixels in the digital picture are extracted. Finally, the CMYK values corresponding to the key words are extracted from the storage module.

According to the disclosed method, a buffer mechanism is added on the basis of a module that can execute all conversions so that most conversions do not need to go through that module, but achieved by searching the buffer. This greatly increases the CMM processing speed and uses less memory. The RGB values after conversions generate the CMYK values to be stored in the buffer. When necessary, the converted CMYK values in the buffer are directly extracted. This method can save a lot of processing time. This also ensures the color consistency in most applications. In short, the invention achieves the goal of saving time and cost.

### BRIEF DESCRIPTION OF THE DRAWINGS

The invention will become more fully understood from the detailed description given hereinbelow illustration only, and thus are not limitative of the present invention, and wherein:

FIG. 1 shows the structure of the disclosed high-speed color match processing system;

FIG. 2 shows the structure of an embodiment system of the invention;

FIG. 3 is a flowchart of the disclosed high-speed color match processing method; and

FIG. 4 is the flowchart of an embodiment method of the invention.

### DETAILED DESCRIPTION OF THE INVENTION

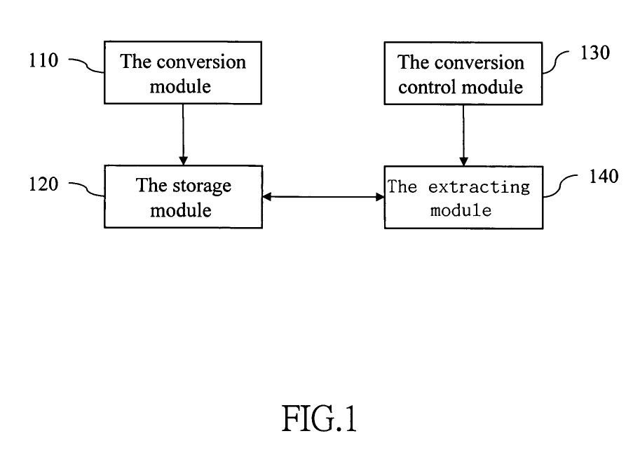

First, we use FIG. 1, to explain the module structure in the disclosed high-speed color match processing system:

(1) The conversion module 110 is used to convert the RGB values of the pixels in a digital picture into the CMYK values used for color printing.

(2) The storage module 120 is used to store the CMYK vlaues. It is preferably a cache memory.

(3) The conversion control module 130 is used to receive a conversion start command and control the beginning of the conversion.

(4) The extracting module 140 is used to extract according to the conversion start command the key words of the RGB values of the pixels in the digital picture. The key word consists of each of the lower 4-bit (or 5-bit) values in the RGB values. The key words are then used to search in the storage module their corresponding CMYK values, thereby converting the RGB values to the CMYK values.

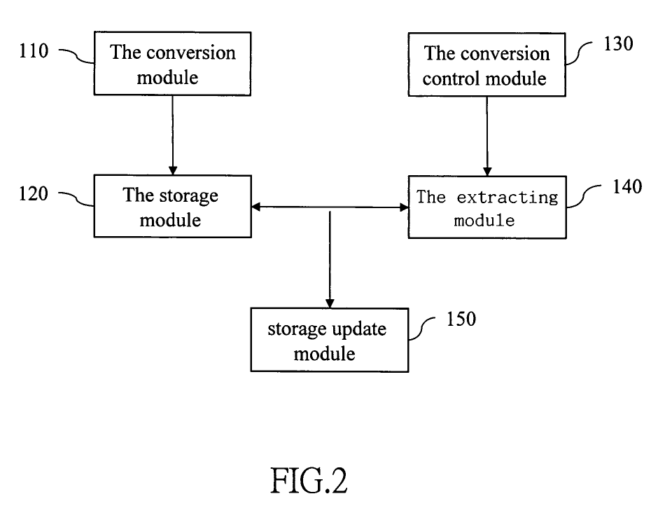

The invention further includes a storage update module 150, as shown in FIG. 2. When the extracting module cannot find from the storage module CMYK values corresponding to the key word of the RGB values of the current pixel, the key word is sent to the conversion module 110 for conversion. The CMYK values thus obtained are stored in the storage module 120, thereby updating the data in the storage module.

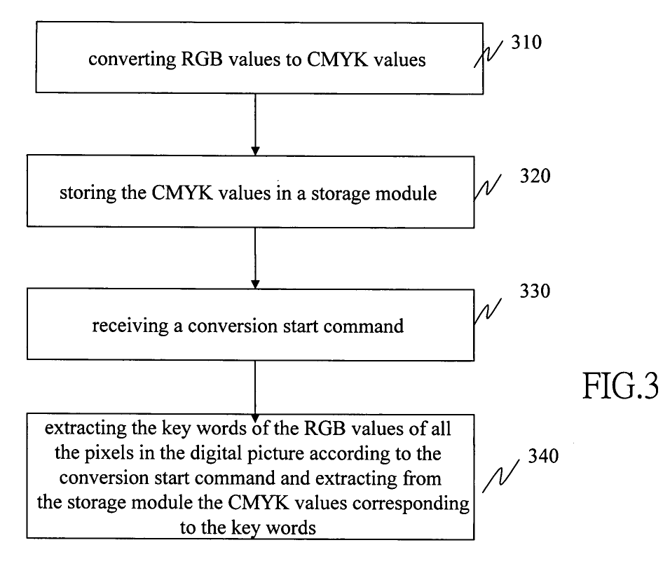

We use FIG. 3 to explain the procedure of the disclosed method. First, the RGB values are converted into CMYK values (step 310). The CMYK values are stored in the storage module (step 320). A conversion start command is received (step 330). According to the conversion start command, the key words of the RGB values of all pixels in the current digital picture are extracted. The key words are used to search their corresponding CMYK values in the storage module, thereby converting the RGB values to the CMYK values (step 340).

We need to establish a color buffer data structure. Since pictures have the gray-scale and color modes, we also need two sets of color buffers, one for the gray-scale values and the other for the color values. The data structure is as follows:

The data structure of each color:

struct _CMM_PIXEL
{

unsigned long RGBcolor;
unsigned long CMYKcolor;

};

Totally 4096 items are reserved for the color data buffer.

#define _CMM_CACHE_SIZE 256*4*4
struct _CMM_CACHE
{

struct _CMM_PIXEL cmm_pixel[_CMM_CACHE_SIZE];

};

This occupies all 32K-bit memory.
Totally 768 items are reserved for the gray-scale color data buffer.

#define _CMM_GRAPHICSCACHE_SIZE 256*3
struct _CMM_GRAPHICSCACHE
{

struct _CMM_PIXEL
cmm_pixel[_CMM_GRAPHICSCACHE_SIZE];

};

This occupies 6K-bit memory.

One has to take into account the system performance when determining the sizes of the buffers. The larger the buffers are, the higher the chances a conversion can be found. Nevertheless, larger buffers may slow down the system operation efficiency.

Since the range of the RGB values is 0--2ˆ24 while the buffer range is smaller than 2ˆ24, it is impossible to record all the RGB colors in the buffer. The buffer can only record those colors that are frequently used recently. Therefore, the computation of the match key words is very crucial. Using the lower 4 bits of the RGB values to form a 12-bit key word can achieve a better efficiency without wasting too much memory. First, the occupied memory is small, totally 2ˆ12=4096 items. Each item contains the RGB and two 4 bytes of the CMYK, totally occupying 32 K bytes of memory. Using the lower 5 bits of the RGB values will result in 2ˆ15=32768 items. However, this will occupy 256K bytes of memory, much larger than the previous case. The reason for choosing the lower 4 bits of the RGB values is that the RGB values are basically encoded in the lower bits than the higher bits. Taking the higher 4 bits for the buffers will result in less than 10% of chances in the match.

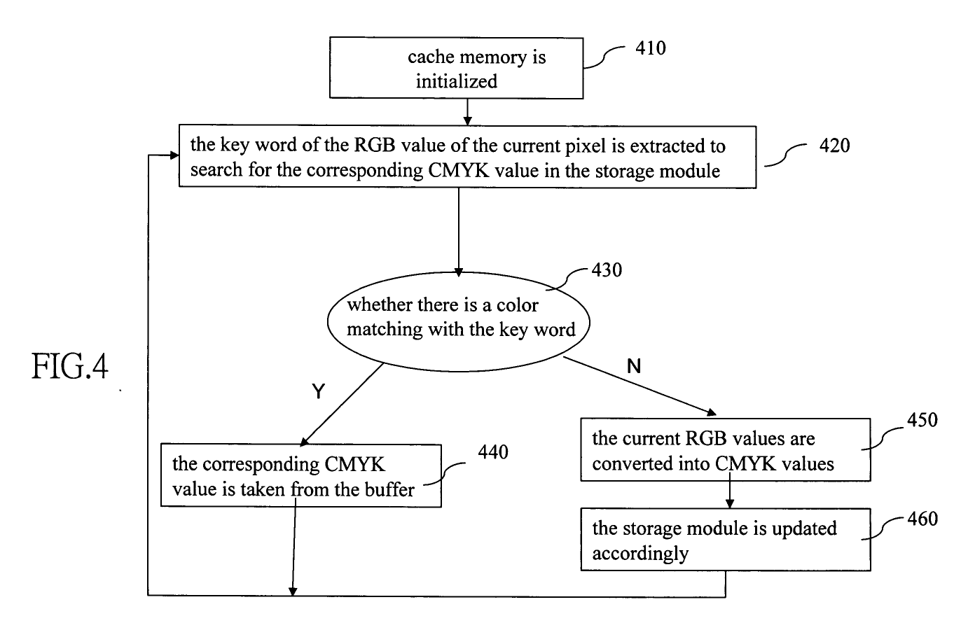

The flowchart of an embodiment of the invention is shown in FIG. 4. First, cache memory is initialized (step 410). According to the conversion start command, the key word of the RGB value of the current pixel is extracted to search for the corresponding CMYK value in the storage module (step 420). Afterwards, the system checks whether there is a color matching with the key word (step 430). If such a color value exists, the corresponding CMYK value is taken from the buffer (step 440). If no corresponding CMYK color is found, the current RGB values are converted into CMYK values (step 450). Finally, the storage module is updated accordingly (step 460).

Certain variations would be apparent to those skilled in the art, which variations are considered within the spirit and scope of the claimed invention.

What is claimed is:

1. A high-speed color match processing system to quickly convert a digital picture from the RGB mode to the CMYK mode, the system comprising:
a conversion pre-processing module, which converts key words of RGB values into CMYK values;
a storage module, which stores the CMYK values;
a conversion control module, which receives a conversion start command and controls the beginning of the conversion; and
an extracting module, which extracts the key word of the RGB values of a pixel in the digital picture according to the conversion start command and uses the key word to search the corresponding CMYK values in the storage module, thereby converting the RGB values to the CMYK values.

2. The high-speed color match processing system of claim 1, wherein the storage module is cache memory.

3. The high-speed color match processing system of claim 1, wherein the key word of the RGB values consists of the lower four bits of the RGB values.

4. The high-speed color match processing system of claim 1, wherein the key word of the RGB values consists of the lower five bits of the RGB values.

5. The high-speed color match processing system of claim 1 further comprising a storage updating module, which, when no corresponding CMYK values are found in the storage module for the key word of the RGB values of the current pixel, sends the key word to the conversion pre-processing module for conversion and stores the converted the CMYK values in the storage module.

6. A high-speed color match processing method to quickly convert a digital picture from the RGB mode to the CMYK mode, the method comprising the steps of:
converting RGB values to CMYK values;
storing the CMYK values in a storage module;
receiving a conversion start command; and
extracting the key words of the RGB values of all the pixels in the digital picture according to the conversion start command and extracting from the storage module the CMYK values corresponding to the key words.

7. The high-speed color match processing method of claim 6, wherein the storage module is cache memory.

8. The high-speed color match processing method of claim 6, wherein the key word of the RGB values consists of the lower four bits of the RGB values.

9. The high-speed color match processing method of claim 6, wherein the key word of the RGB values consists of the lower five bits of the RGB values.

10. The high-speed color match processing method of claim 6 further comprising the step of updating data storage, which, when no corresponding CMYK values are found in the storage module for the key word of the RGB values of the current pixel, converts the key word into the corresponding CMYK values and stores the converted the CMYK values.
